(19) United States
(12) Patent Application Publication
(10) Pub. No.: US 2018/0106852 A1
(43) Pub. Date: Apr. 19, 2018

(54) Field Control Element For A High-Voltage Cable Accessory And Method of Optically Measuring Partial Discharges

(71) Applicants: Tyco Electronics Raychem GmbH, Ottobrunn (DE); IPH GmbH, Berlin (DE)

(72) Inventors: Alexander Eigner, Munchen (DE); Thomas Kranz, Muchen (DE); Gerd Heidmann, Berlin (DE); Klaus Vaterrodt, Berlin (DE)

(73) Assignees: Tyco Electronics Raychem GmbH, Ottobrunn (DE); IPH GmbH, Berlin (DE)

(21) Appl. No.: 15/847,200

(22) Filed: Dec. 19, 2017

Related U.S. Application Data
(63) Continuation of application No. PCT/EP2016/061242, filed on May 19, 2016.

(30) Foreign Application Priority Data
Jun. 22, 2015 (EP) 15173098.3

(51) Int. Cl. G01R 31/12; H01R 13/53; H02G 15/064; H02G 15/184

(52) U.S. Cl. CPC G01R 31/1272; H01R 13/53; G02B 6/442; H02G 15/184; G01R 31/1218; H02G 15/064

(57) ABSTRACT

A field control element for a high-voltage cable accessory comprises an electrically insulating material. The electrically insulating material includes a fluorescent dye adapted to convert a first radiation having a first wavelength and generated by an electrical discharge into a second radiation having a second wavelength longer than the first wavelength.

### CROSS-REFERENCE TO RELATED APPLICATIONS

This application is a continuation of PCT International Application No. PCT/EP2016/061242, filed on May 19, 2016, which claims priority under 35 U.S.C. § 119 to European Patent Application No. 15173098.3, filed on Jun. 22, 2015.

### FIELD OF THE INVENTION

The present invention relates to a high-voltage cable accessory and, more particularly, to a field control element for a high-voltage cable accessory.

### BACKGROUND

High-voltage cable accessories are used to connect high-voltage power cables to electrical equipment such as overhead lines, transformers, search arrestors, switchgears, etc. The accessories either insulate or control the electrical field of power cables at different ambient conditions. High-voltage cable accessories are expected to have a lifetime of more than 40 years without any failure. In order to achieve this requirement, the insulation system of the cable accessory and its performance have to be checked regularly. Moreover, due to the fact that a manual installation is always necessary for erecting a termination or installing a cable joint, faults during the installation must also be considered; such mistakes can lead to an electrical breakdown with a subsequent arc inside the termination. Consequently, there is a need for a diagnostic method that provides information about the current status of the cable accessories including their remaining lifetime.

The most commonly used diagnostic method for providing real time information about the status and the remaining lifetime of cable accessories is the electrical partial discharge (PD) measurement. Electric discharges that do not completely bridge two electrodes or conductors in close proximity to each other are called partial discharges. Originating with defects such as cavities or inclusions and interfaces to other materials, in particular to conductors carrying high-voltage, partial discharges lead to the formation of “trees” that grow over time and eventually cause an electric break down. Such PD trees typically have a length of more than 1 μm. The magnitude of such partial discharges is usually small and the amount of charge transferred is in the range of 10 to a few hundred Pico-Coulombs (pC). For a partial discharge test, a suitably high AC or DC voltage is applied to the conductors surrounding the insulation material under test. Alternatively, the discharge can be detected under normal operating conditions depending on the defect and energized system characteristics.

The most commonly used diagnostic method for obtaining the status of high-voltage cable accessories is the electrical partial discharge measurement according to the IEC standard 60270 (“High-voltage test techniques—Partial discharge measurement”, IEC 60270:2000). This setup consists basically of a high-voltage source (which could be based on different techniques such as standard 50 Hz or resonant system), a coupling capacitance for signal extraction, and a quadrupole for the adaption of the PD signals for direct measurement. Each partial discharge event causes a short current signal which can be detected with the connected measuring device.

PD diagnostics is therefore based on the measurement of electrical signals with very small amplitude. A disadvantage of this technique is that due to the small amplitude it is very sensitive to electrical noise caused by external electrical fields such as from transformers, overhead lines, etc. Consequently, the electrical partial discharge measurement in a noisy environment (e. g. during on-site tests) does not always allow a proper interpretation of the partial discharge measurement results and thus an understanding of the condition of high-voltage equipment is not possible.

Partial discharges also produce light and therefore it is possible to detect partial discharges by measuring the light generated thereby. Such an optical PD measurement advantageously is not affected by electrical noise from the surrounding high-voltage equipment. For instance by using fiber optic sensors that are integrated into high-voltage accessories, a real time damage monitoring based on an optical PD measurement could be demonstrated. Such a fiber optic sensor arrangement using fluorescent optical fibers is for instance described in the article W. R. Habel et al.: “Fibre-optic sensors for early damage detection in plastic installations of high-voltage facilities”, XVII International Symposium on High-voltage Engineering, Hannover, Germany, Aug. 22-26, 2011. A detailed description of this system used with stress cones is also given in the PhD Thesis “Dielectric strength behavior and mechanical properties of transparent insulation materials suitable to optical monitoring of partial discharges” by Chaiyaporn Lothongkam, Fakultät für Elektrotechnik and Informatik der Gottfried Wilhelm Leibniz Universitat Hannover, 25 Jul. 2014.

This conventional system, however, suffers from non-satisfactory signal strength in case the partial discharge occurs at a site distanced away from the fluorescent optical fiber. Moreover, only specific fluorescent fiber optic sensors can be used, which have to be mounted as close as possible to the location where the partial discharges have to be detected. In order to achieve a sufficiently high signal yield, this known system needs a large surface of the fluorescent optical fiber to be in contact with the stress cone. Therefore, a long fiber is embedded in an outer region of the stress cone to be arranged helically wound around a longitudinal axis of the stress cone. For mounting the stress cone, however, the cone normally has to be expanded, sometimes by 400% of the initial diameter. The optical fiber suffers from the problem that it cannot be expanded in its length to a comparable extent, so that it can be damaged or break during the mounting process.

### SUMMARY

A field control element for a high-voltage cable accessory according to the invention comprises an electrically insulating material. The electrically insulating material includes a fluorescent dye adapted to convert a first radiation having a first wavelength and generated by an electrical discharge into a second radiation having a second wavelength longer than the first wavelength.

### BRIEF DESCRIPTION OF THE DRAWINGS

The invention will now be described by way of example with reference to the accompanying Figures, of which:

FIG. 1 is a schematic diagram of wavelength ranges of radiation generated by electrical discharges in different media;

FIG. 2 is a schematic diagram of a Stokes shift of the present invention;

FIG. 3 is a sectional view of a high-voltage outdoor termination according to the invention;

FIG. 4 is an enlarged sectional view of the high-voltage outdoor termination of FIG. 3 with an optical detector;

FIG. 5 is a sectional view of a switchgear termination according to the invention;

FIG. 6 is an enlarged sectional view of the switchgear termination of FIG. 5 with an optical detector;

FIG. 7 is a sectional view of a cable joint according to the invention; and

FIG. 8 is an enlarged section view of the cable joint of FIG. 7 with an optical detector.

### DETAILED DESCRIPTION OF THE EMBODIMENTS

Exemplary embodiments of the present invention will be described hereinafter in detail with reference to the attached drawings, wherein like reference numerals refer to like elements. The present invention may, however, be embodied in many different forms and should not be construed as being limited to the embodiments set forth herein. Rather, these embodiments are provided so that the present disclosure will be thorough and complete and will fully convey the concept of the disclosure to those skilled in the art.

The term “high-voltage” as used in the following is intended to relate to voltages above approximately 1 kV. In particular, the term high-voltage is intended to comprise the usual nominal voltage ranges of power transmission, namely medium voltage (about 3 kV to about 50 kV), high-voltage (about 50 kV to about 110 kV), and also extra high-voltage (up to presently about 500 kV). Of course also higher voltages may be considered in the future. These voltages may be direct current (DC) or alternating current (AC) voltages. In the following, the term “high-voltage cable” is intended to signify a cable that is suitable for carrying electric current of more than about 1 A at a voltage above approximately 1 kV. Accordingly, the term “high-voltage accessory” is intended to signify a device that is suitable for interconnecting high-voltage facilities and/or high-voltage cables. In particular, a high-voltage accessory may either be an end termination or a cable joint.

The term “partial discharge” as used in the following therefore is intended to describe short term, low-energy and locally limited discharges within an insulation, which do not lead to a complete electric break down but irreversibly damage the insulation. The term “partial discharge” in particular is intended to comprise so-called “inner partial discharges” which occur within non-gaseous insulating materials.

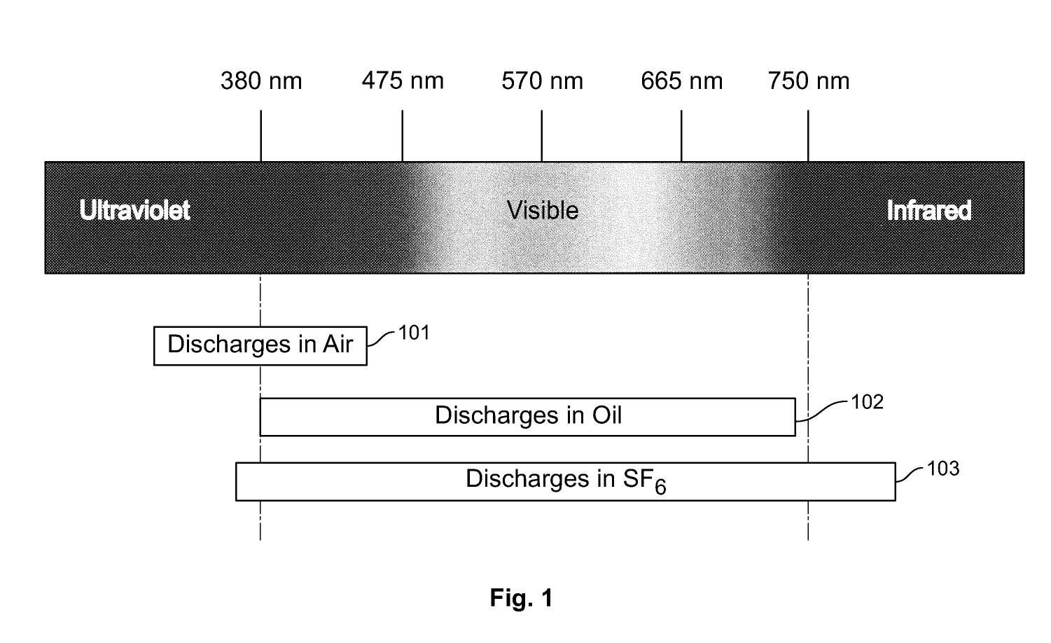

FIG. 1 shows a schematic comparison of the wavelength ranges of radiation that is generated by electrical discharges in different electrically insulating media. Optical partial discharge detection is based on the detection of the light which is generated as a result of the physical breakdown processes during the electrical discharge. The wavelength of the generated light depends on the insulating material where the discharges occur; it can be differentiated into three main groups which are used in high-voltage engineering: air, oil, and sulfur hexaflouride (SF6).

The wavelength range 101 for discharges in air, as shown in FIG. 1, is partly in the ultraviolet region and usually below 475 nm. Discharges in oil 102 cause a radiation emission in a wavelength region from about 380 nm to around 750 nm. Furthermore, sulfur hexafluoride SF6 is an insulator that is frequently used with switchgear. As shown in FIG. 1, discharges occurring in SF6 generate radiation in the wavelength range 103 from below 380 nm up to around 800 nm.

Within solid materials most of the discharges are related to air discharges as the void contains air or the failure is often caused by air entrapment. Based on this, the characteristic wavelength of partial discharges in plastic insulations, such as field control elements for high-voltage cable accessories, can be assumed to correspond to the wavelength range 101 of discharges in air. However, a direct real time monitoring of the radiation which is generated by discharges within air is currently difficult or impossible due to the very short wavelength; the wavelength of discharges in air has to be transferred into a range at which such detection can be properly conducted.

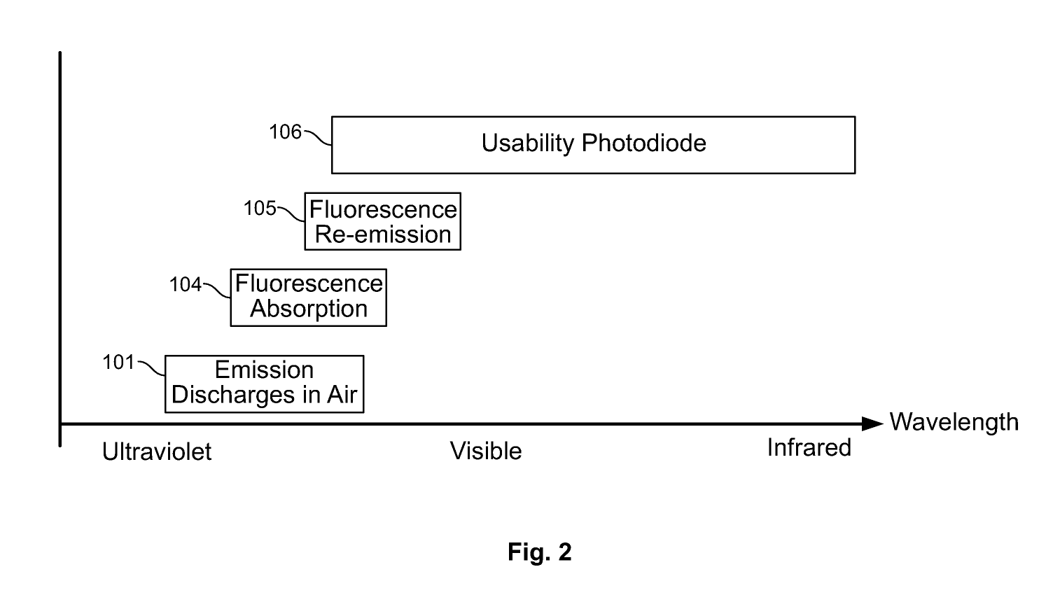

FIG. 2 shows the wavelengths of the different steps for optical partial discharge measurement in high voltage cable accessories. Starting from the wavelength range 101 of the light primarily caused by discharges in air, the light is first absorbed by a fluorescent dye; the adsorption of the chosen fluorescence molecule happens in a wavelength range 104 which is as close as possible to the emission wavelength range 101.

The fluorescent dye may comprise any suitable fluorophore that does not impair the insulation or the mechanical performance of the insulation material. In an embodiment, the fluorescent dye has an absorption fluorescence between 350 nm and 500 nm, and an emission fluorescence between 500 nm and 800 nm.

A fluorophore (or fluorochrome) is a fluorescent chemical compound that can re-emit light upon light excitation. Fluorophores typically contain several combined aromatic groups, or plane or cyclic molecules with several 7C bonds. Fluorophores can be covalently bonded to a macromolecule, for instance polysiloxane. However, fluorophores may also be used alone, for instance be dispersed in a liquid insulator such as silicone oil. The fluorophore absorbs light energy of a specific wavelength and re-emits light at a longer wavelength. The absorbed wavelengths, energy transfer efficiency, and time before emission depend on both the fluorophore structure and its chemical environment, as the molecule in its excited state interacts with surrounding molecules. Wavelengths of maximum absorption (approximately corresponding to the excitation wavelength) and emission (for example, Absorption/Emission=485 nm/517 nm) are the typical terms used to refer to a given fluorophore, but the whole spectrum may be important to consider. The excitation wavelength spectrum may be a very narrow or broader band, or it may be all beyond a cutoff level. The emission spectrum is usually sharper than the excitation spectrum, and it is of a longer wavelength and correspondingly lower energy. Excitation energies range from ultraviolet through the visible spectrum, and emission energies may continue from visible light into the near infrared region. Main characteristics of fluorophores are:
Maximum excitation and emission wavelength (expressed in nm): corresponds to the peak in the excitation and emission spectra (usually one peak each).
Extinction coefficient (or molar absorption, in Mol-1 cm-1): links the quantity of absorbed light, at a given wavelength, to the concentration of fluorophore in solution.
Quantum yield: efficiency of the energy transferred from incident light to emitted fluorescence (corresponding to the number of emitted photons per absorbed photons).
Lifetime (in picoseconds): duration of the excited state of a fluorophore before returning to its ground state. It refers to the time taken for a population of excited fluorophores to decay to 1/e (≈0.368) of the original amount.
Stokes shift: difference between the maximum excitation and maximum emission wavelengths.

Depending on the chosen fluorescence dye, the re-emission of radiation from the excited molecule is of a lower wavelength 105. This effect is the Stokes shift exhibited by most fluorescent materials. When comparing the re-emitted wavelength range 105 with the wavelength range 106 where the photodiode usually is sensitive, it becomes clear that the photodiode is able to detect almost all of the re-emitted radiation in the range 105, but would be able to detect very little of the primarily emitted radiation in the range 101.

The wavelength conversion takes place within the bulk material of the insulator, especially within a field control element, by providing a fluorescent dye directly within the material of the insulator. Any fluorescent particles which do not have an influence on the installation performance of the insulation material and have a suitable absorption range 104 and re-emission range 105 can be used according to the present invention. In particular, when providing a field control element with the fluorescent dye, the emission by the partial discharges can be transformed into radiation with a higher wavelength than directly at the site of the formation of the partial discharge. This lower energy radiation can pass through the insulator material to be detected by an optical detector. The re-emitted radiation with its lower energy suffers less damping when travelling through the insulator material than the high-energy primary radiation. This enhances the sensitivity of the monitoring system compared to conventional systems that detect the primary radiation by means of fluorescent optical fibers.

The re-emitted radiation may be absorbed by other fluorescence dye molecules because the absorption and re-emission spectra 104, 105 overlap. Consequently, the radiation is amplified on its path to the detector and therefore the light yield can be enhanced compared to known systems using fluorescence dye clad optical fibers. As fluorescence re-emission takes place very shortly after the absorption event, no substantial time delay is caused by this additional step (for commonly used fluorescent compounds, typical excited state decay times for photon emissions with energies from the UV to near infrared are within the range of 0.5 to 20 nanoseconds).

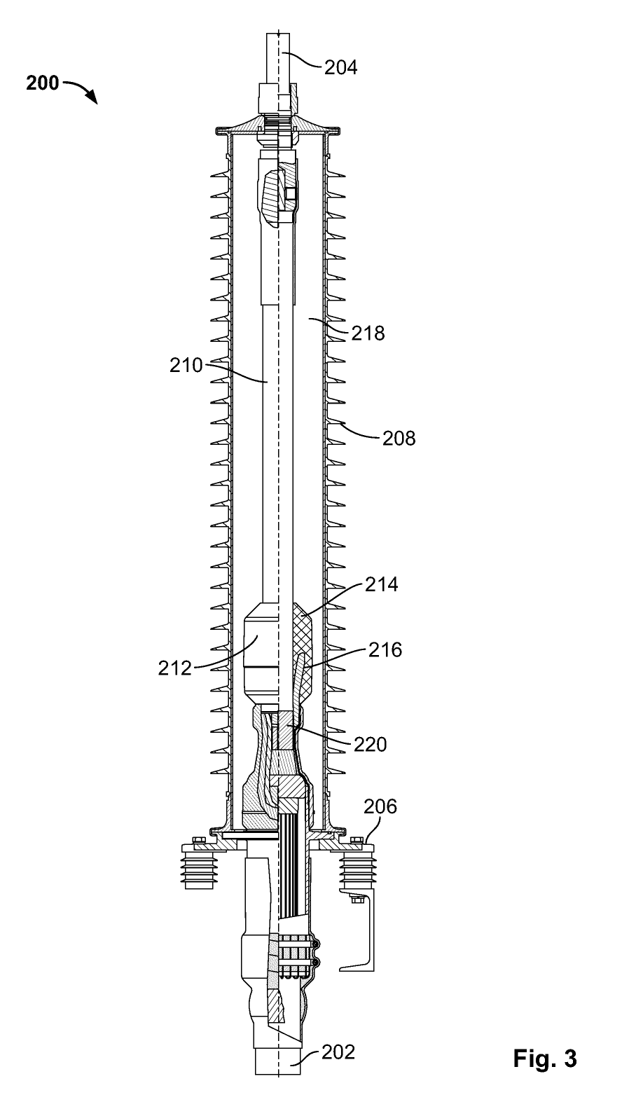

An embodiment of a high-voltage outdoor termination 200, commonly used for overhead lines, is shown in FIG. 3. The termination 200 has a cable 202 with a cable lug 204 for connecting the cable 202 with high-voltage facilities. The outdoor termination 200 is installed at a base plate 206. A housing 208, which is fabricated from porcelain in an embodiment, encloses the inner components and protects them from the surroundings. The housing 208 encloses an insulating area 218 which is filled with an electrically insulating filling. The insulating filling may comprise a gas, such as air or SF6, or a liquid, such as oil. The insulating area 218 is essentially cylindrical and rotationally-symmetric.

The high-voltage cable 202 is inserted into the cable end termination 200 and is deprived of its outer layers, such as the cable jacket, cushioning layers and the metallic shield. A normally semi-conductive outer cable shield 220 is inserted into the area of a field control element 212 within the housing 208. Inside the insulating area 218 with the insulating filling, only a cable conductor 210 of the cable 202 surrounded by a cable insulation is present.

The field control element 212 shown in FIG. 3, also called a stress cone, is provided for controlling the electrical field at the transition between the insulation and the conductor 210 of the cable 202. The field control element 212 is arranged at a location within the insulating area 218 where the electrical field stress would be too high for the insulating filling within the insulating area 218. The field control element 212 is formed from an insulating field control body 214 and comprises at least one electrically conductive or semi-conductive deflector 216 for controlling the electrical. The field control element 212 is formed by a transparent or translucent elastomeric field control body 214 with an integrated deflector 216 for influencing the electric field profile within high-voltage devices such as cable accessories. In an embodiment, the field control element 212 is formed as a cone with the integrated deflector 216 that is formed to deflect the electric field lines by geometric/capacitive effects so that the field strength outside the field control element 212 is reduced to uncritical values.

As shown in FIG. 3, the field control element 212 is formed as a cone with an inner hollow cylindrical opening for receiving the cable 210. This inner hollow cylindrical opening is dimensioned to form a press fit between the cable insulation of the cable 210 and the field control element 212. At least a part of the field control element 212 is provided with a fluorescent dye. In an embodiment, the fluorescent dye is provided in the insulating field control body 214 which usually is formed from a polysiloxane elastomer; fluorescent particles can be homogeneously distributed within the polysiloxane material.

Alternatively or additionally, only limited areas or layers of the field control element 212 may contain a fluorescent dye. The dye may also be embedded in electrically conductive or semi-conductive plastic parts, provided these parts are sufficiently transparent for the absorbed and re-emitted radiation. Moreover, the insulating filling of the insulating area 218 may also contain a fluorescent dye; in this case the filling comprises electrically insulating oil, such as silicone oil with fluorescent particles dispersed therein. Providing the insulating filling with a fluorescent dye can be done in addition or alternatively to providing the field control element 212 with a fluorescent dye. Of course, the same or different fluorophores can be used in the solid and the liquid matrix, respectively.

A detection of the occurrence of partial discharges can be achieved by optically detecting the re-emitted radiation by an optical detector such as at least one photodetector, a photodiode, a CCD, or the like. The optical detector may be located in the vicinity of the field control element 212, but can also be arranged distanced therefrom, for instance within the insulating area 218. Most of the partial discharges are caused in the area of the field control element 212, and in particular close to the deflector 216, because of an improper installation of the field control element 212 or a defective cable treatment which causes air entrapment. Discharges in other areas can be detected for instance electrical discharges in oil due to moisture ingress into the insulating area 218.

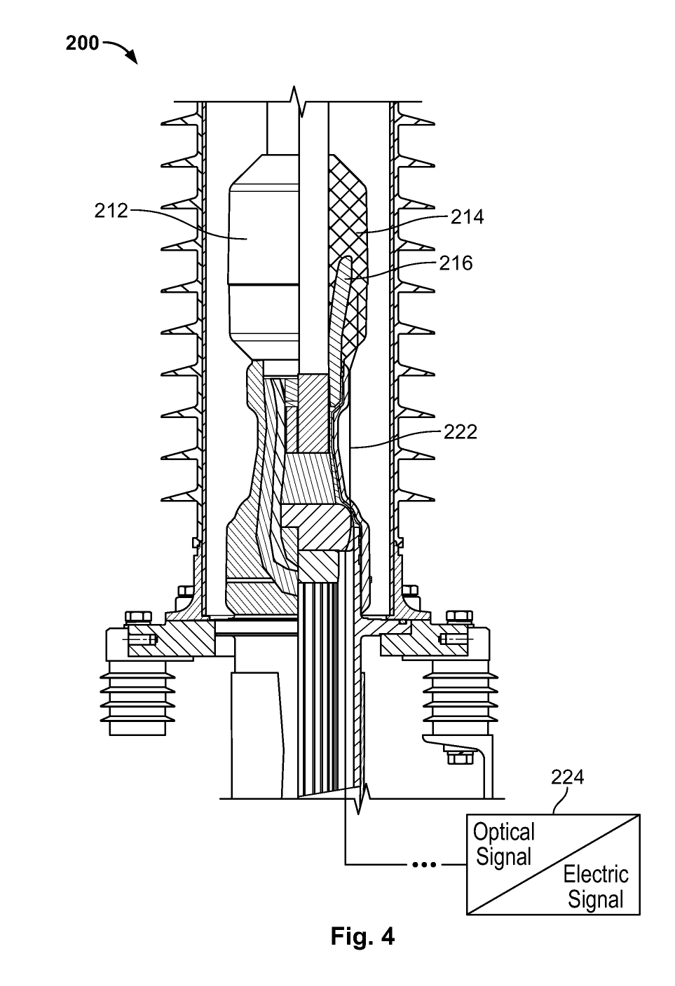

An embodiment of the high-voltage outdoor termination 200 with an integrated optical detector for detecting the re-emitted radiation is shown in FIG. 4. A fluorescent dye is provided in the field control element 212. In particular, the fluorescent particles may be contained in the field control body 214 which may be an electrically insulating polysiloxane. The electrically conductive deflector 216 usually is intransparent and therefore not provided with the fluorescent dye. However, in case the material of the deflector 216 is sufficiently transparent for the adsorbed and re-emitted radiation, the deflector 216 may also comprise fluorescent particles.

As shown in FIG. 4, the optical detector comprises an optical fiber 222 which transmits the re-emitted radiation to an optical transducer 224 which generates an electrical output signal from the optical signal. Such an optical transducer 224 may, for instance, comprise a photodiode for converting the sensed radiation into an electrical signal. The signal generated by the transducer 224 may be further processed by a central monitoring unit which may also be configured to monitor the output signals transmitted from a plurality of such transducers 224.

A coupling end of the optical fiber 222, as shown in FIG. 4, is located close to the deflector 216 because here most of the partial discharges are to be expected. However, it is clear for a person skilled in the art that the position of the coupling end of the optical fiber 222 may be varied. Moreover, in other embodiments, a plurality of optical fibers may be arranged at different positions. For enhancing the amount of radiation taken up by the fiber, in an embodiment, a lens system be provided at the optical fiber 222.

The optical fiber 222 is a polymeric optical fiber (POF) that this inserted into the insulating field control body 214 in the embodiment shown in FIG. 4. In order to ensure a similar optical reflection between the field control element 212 and the polymeric optical fiber 222, a separate layer with an optically optimized reflection behavior can be provided at the interface between the two surfaces. However, it is clear for a person skilled in the art that other optical detectors, for instance, photodetectors that are directly arranged at the field control element 212, could alternatively be used. Moreover, the optical fiber 222 may also be arranged at the surface of the stress cone 212 or within the filling of the insulating area 218. The optical fiber 222 has a sensing region at least partly embedded in the field control element 212 or disposed at an outer surface of the field control element 212. Furthermore, an autarkic optical detector that comprises an optical transducer, signal processor, an energy harvesting power source, and a wireless communication unit may be used for detecting the re-emitted radiation. Such an autarkic optical detector either continuously transmits the information about occurring partial discharging events or stores the measurement data and outputs them only on request from outside. In other embodiments, more than one optical fiber 222 or a plurality of autarkic optical detectors can be provided at the high-voltage accessory in order to cover all possible areas where partial discharges might occur.

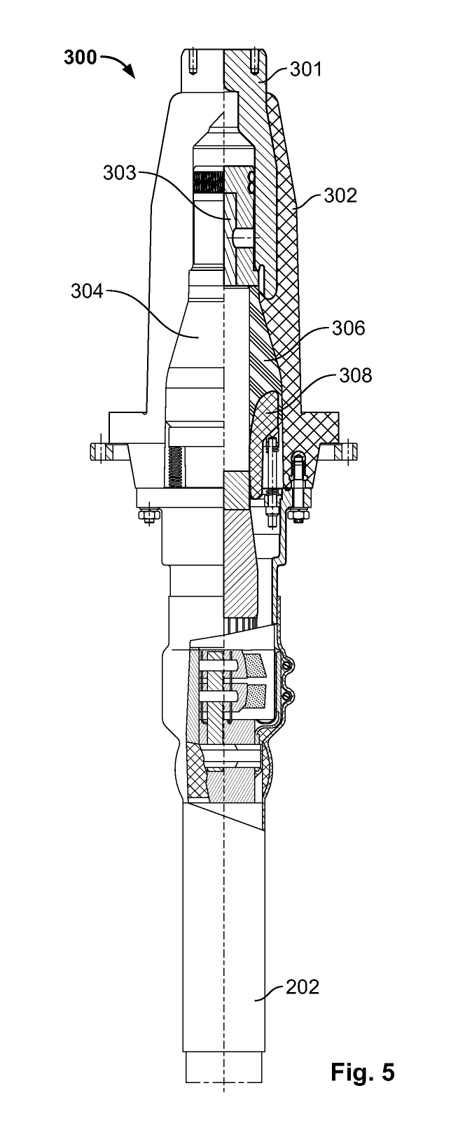

In another embodiment shown in FIG. 5, the principles of the high-voltage outdoor termination 200 can be applied to a switchgear termination 300. Like reference numbers refer to like elements, and the features which are the same as those in FIGS. 3 and 4 will not be repeated in detail for the sake of brevity.

The switchgear termination 300 shown in FIG. 5 is designed to be installed in cable entry housings of a gas insulated switchgear. Such a switchgear termination 300 usually operates in SF6, but also in insulating liquids like transformer oil. As shown in FIG. 5, the termination 300 comprises an insulating housing 302 which, in an embodiment, is formed from a resin. The cable 202 is inserted into the housing with its end being stripped of its outer layers, such as the cable jacket, cushioning layers, and the metallic shield. The normally semi-conductive outer cable shield 220 is inserted into the area of a field control element 304. Inside the housing 302 of the switchgear termination 300 there may be provided an additional oil filling. At a peripheral end, a connector 301 is attached to a conductive core 303 of the cable 202.

The field control element 304, as shown in FIG. 5, comprises an insulating field control body 306 and a deflector 308. The field control body 306 is formed from a translucent or transparent polysiloxane which is provided with a fluorescent dye. The field control element 304 is disposed in a region of the termination 300 where the highest stress due to the electrical field is to be expected. By providing the field control element 304 with a fluorescent dye, partial discharges can be monitored within the termination 300 by providing an optical detector within or close to the field control element 304. Alternatively or additionally, the fluorescent dye may also be provided in other insulating parts within the housing 302.

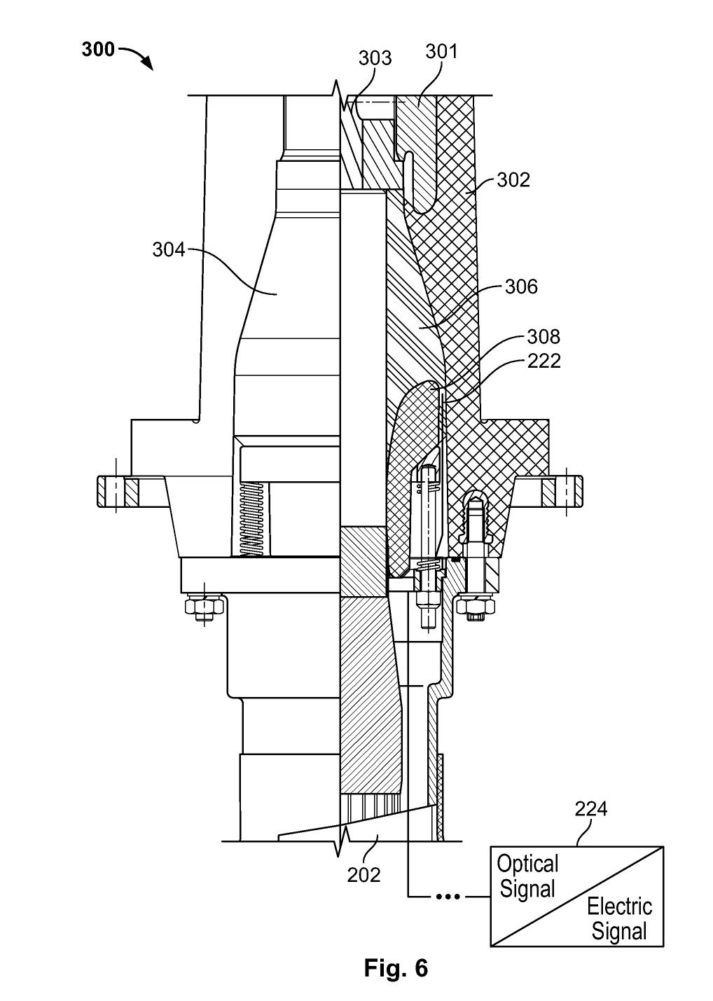

A switchgear termination 300 having an optical fiber 222 and an optical transducer 224, analogously to the arrangement of FIG. 4, is shown in FIG. 6. The optical fiber 222 is embedded inside the field control body 306 of the field control element 304 at a position close to the deflector 308. In other embodiments, the optical fiber 222 may be located at any other suitable position and may also be arranged at the outside of the field control element 304, and in some embodiments, helically wound around the field control element 304.

When a partial discharge occurs, light is emitted and this primary radiation is converted by the fluorescent dye in the polysiloxane material into a secondary re-emitted radiation having lower energy and a longer wavelength. The radiation re-emitted by the fluorescence dye partly enters the optical fiber 222 and is transmitted to the optical transducer 224. The transducer 224 converts the optical signal into an electric signal that may be further processed by additional external electronic devices.

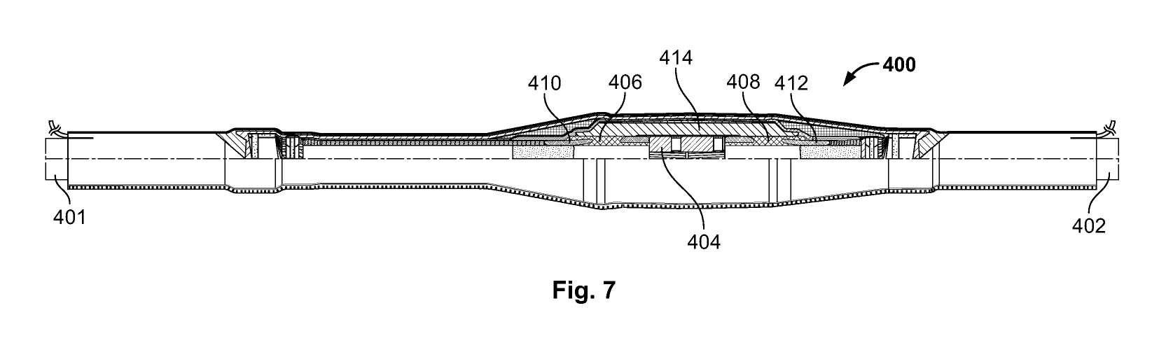

In another embodiment shown in FIG. 7, the principles of the high-voltage outdoor termination 200 and the switchgear termination 300 can be applied to a high voltage cable joint 400. Like reference numbers refer to like elements, and the features which are the same as those in FIGS. 3 and 4 will not be repeated in detail for the sake of brevity.

The cable joint 400, as shown in FIG. 7, is adapted for connecting two cables 401, 402 with each other. A mechanical connector 404 interconnects the cores of the two cables 401, 402. At each cable 401, 402, a field control element 406, 408 with deflectors 410, 412 is provided. A silicone rubber main body 414 covers the connection region and may also comprise additional deflecting layers.

The field control elements 406, 408 as well as the main body 414 may be provided with a fluorescent dye. Partial discharges that occur inside the cable joint 414 are absorbed by the fluorescent dye. A re-emitted secondary radiation is generated from the primary radiation caused by the PD and can be detected by any suitable optical detector.

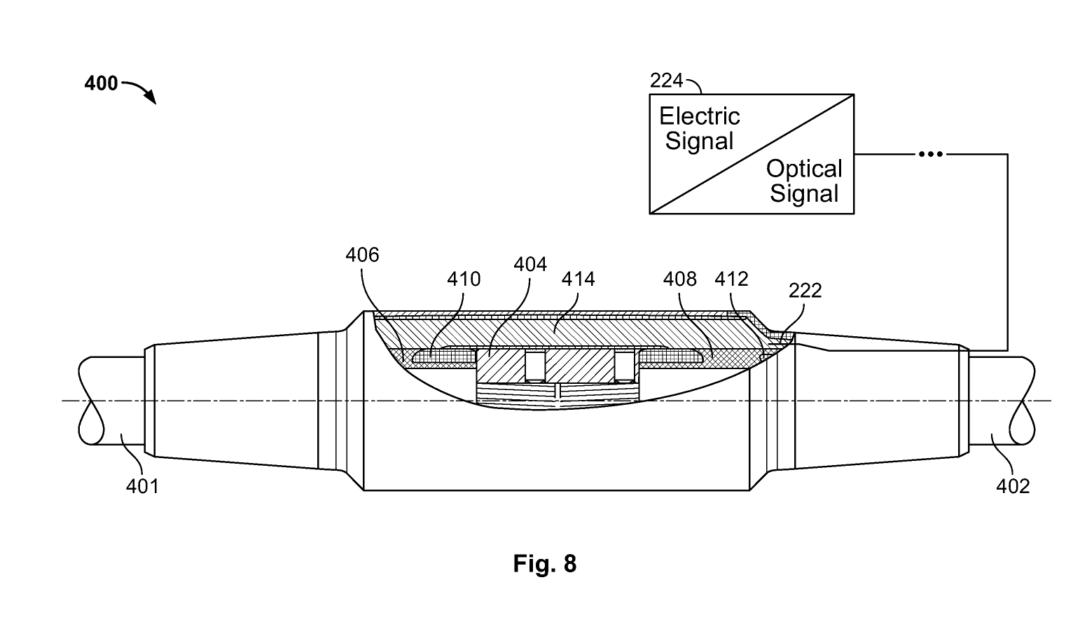

An optical fiber 222, as shown in FIG. 8, is inserted into the main body 414 for transmitting the re-emitted radiation to the optical transducer 224. The tip of the optical fiber 222 is arranged in the vicinity of the deflector 412 because this is the most critical location regarding the occurrence of partial discharges. However, also partial discharges occurring closer to the mechanical connector 404 will also be detected by the optical fiber 222 because the fluorescent radiation will travel through the main body 414 until it is picked up by the optical fiber 222.

The optical transducer 224 can also be connected to a superordinate electronic unit for further processing of the electric signal.

The integration of optical partial discharge detection on the basis of fluorescent silicone rubber in high voltage cable accessories is possible; during different tests it was verified that the modified silicone rubber has no negative impact to the fluorescent behavior and can be used for optical partial discharge detection. The on-site-PD-measurement of the cable accessories disclosed herein have a sensitivity comparable to an electrical partial discharge measurement but avoids complications of noise. Partial discharges can be detected which occur within the fluorescence tagged insulator(s) but also discharges that occur in the optically coupled environment.

What is claimed is:

1. A field control element for a high-voltage cable accessory, comprising:
an electrically insulating material including a fluorescent dye adapted to convert a first radiation having a first wavelength and generated by an electrical discharge into a second radiation having a second wavelength longer than the first wavelength.

2. The field control element of claim 1, wherein the electrically insulating material comprises at least one translucent or transparent region of polysiloxane.

3. The field control element of claim 1, wherein the fluorescent dye is homogenously distributed within the at least one translucent or transparent region.

4. The field control element of claim 1, further comprising an optical detector mechanically and optically coupled with the field control element.

5. The field control element of claim 4, wherein the optical detector detects the second radiation.

6. The field control element of claim 5, wherein an optical fiber of the optical detector is adapted to be inserted into the electrically insulating material.

7. The field control element of claim 4, further comprising a layer with an optically optimized reflection behavior disposed at an interface between the optical detector and the electrically insulating material.

8. The field control element of claim 1, wherein the fluorescent dye is a fluorophore that does not impair an insulative or a mechanical performance of the insulating material.

9. A high-voltage cable accessory for encompassing part of a cable, comprising:
an electrically insulating material including a fluorescent dye adapted to convert a first radiation having a first wavelength and generated by an electrical discharge into a second radiation having a second wavelength longer than the first wavelength, the electrically insulating material formed as a field control element and/or a further insulating element.

10. The high-voltage cable accessory of claim 9, wherein the high-voltage cable accessory is a termination or a cable joint.

11. The high-voltage cable accessory of claim 10, wherein the high-voltage cable accessory is the termination and the further insulating element is an insulating area filled with the electrically insulating material and enclosed by a housing of the termination.

12. The high-voltage cable accessory of claim 10, wherein the high-voltage cable accessory is the cable joint and the further insulating element is a main body covering a connection region of the cable joint.

13. A monitoring system for detecting an electrical discharge in a high-voltage cable accessory, comprising:
the high-voltage cable accessory having an electrically insulating material including a fluorescent dye adapted to convert a first radiation having a first wavelength and generated by an electrical discharge into a second radiation having a second wavelength longer than the first wavelength, the electrically insulating material formed as a field control element and/or a further insulating element; and
an optical detector capable of detecting the second radiation.

14. The monitoring system of claim 13, wherein the optical detector has a sensing region at least partly embedded in the field control element or disposed at an outer surface of the field control element.

15. The monitoring system of claim 13, wherein the optical detector has an optical fiber capable of transmitting the detected second radiation and an optical transducer capable of generating an electrical signal from the second radiation.

16. The monitoring system of claim 15, wherein the optical transducer is a photodiode.

17. A method of detecting and/or monitoring partial discharges, comprising:
providing a high-voltage cable accessory having an electrically insulating material including a fluorescent dye;
optically sensing a first radiation having a first wavelength and generated by an electrical discharge using the fluorescent dye; and
converting the first radiation having the first wavelength into a second radiation having a second wavelength longer than the first wavelength using the fluorescent dye.

18. The method of claim 17, wherein the first wavelength is below 400 nm.

19. The method of claim 18, wherein the fluorescent dye has an absorption fluorescence between 350 nm and 500 nm and an emission fluorescence between 500 nm and 800 nm.
